(19) United States
(12) Patent Application Publication
(10) Pub. No.: US 2016/0079075 A1
(43) Pub. Date: Mar. 17, 2016

(54) DETERMINATION OF ETCHING PARAMETERS FOR PULSED XENON DIFLUORIDE (XEF2) ETCHING OF SILICON USING CHAMBER PRESSURE DATA

(71) Applicant: STC. UNM, Albuquerque, NM (US)

(72) Inventors: Zayd LESEMAN, Albuquerque, NM (US); Khawar ABBAS, Portland, OR (US); Joseph BUTNER, Albuquerque, NM (US); Mirza ELAHI, Albuquerque, NM (US); Denise PINON, Rio Rancho, NM (US)

(21) Appl. No.: 14/785,819

(22) PCT Filed: Apr. 24, 2014
(86) PCT No.: PCT/US2014/035260

§ 371 Date: Oct. 20, 2015

Related U.S. Application Data
(60) Provisional application No. 61/816,161, filed on Apr. 26, 2013.

(51) Int. Cl. H01L 21/3065; H01L 21/66; H01L 21/67

(52) U.S. Cl. CPC H01L 21/3065; H01L 21/67253; H01L 21/67069; H01L 22/26

(57) ABSTRACT

A method for determining depletion of an etchant, an etch depth, and an etch rate during an etch of a material such as Si using an etchant such as xenon difluoride (XeF₂) in a pulsed etching system in real time measuring pressure within a closed system during the etch. Coupling the pressure data with the knowledge of the chemical reactions allows for the determination of the etching parameters of interest. While the etch of Si using XeF₂ is used for demonstration, the method may be generalized to any closed volume system provided there is a net change in number of moles of gaseous species present in the system before and after the reaction.

### PRIORITY

This application claims priority to provisional U.S. Patent Application Ser. No. 61/816,161 filed Apr. 26, 2013, the disclosure of which is herein incorporated by reference in its entirety.

This invention was made with government support under Grant No. 1056077 awarded by the National Science Foundation (NSF) and Grant No. 1042062 awarded by the NSF-Nano Undergraduate Education Program. The government has certain rights in the invention.

### TECHNICAL FIELD

The present teachings relate to the field of dry etching a material and, more particularly, to the real-time measurement of etch parameters such as etchant depletion, etch depth, and etch rate during an etch.

### BACKGROUND

Etching of a material such as silicon using various wet etches, plasma etches, and dry etches, for example during the formation of a microelectronic device, is well established. Due to their simplicity and excellent selectivity, wet etches were initially used during early microelectronics fabrication. Wet etches were compatible with relatively large feature sizes and rigid substrates of early devices, which did not suffer from reduced device yields resulting from, for example, surface tension of the wet etchant. However, with reduced feature sizes and the need for freestanding devices to form microelectromechanical systems (MEMS), surface tension of the etchant began to have deleterious effects on device yields. Plasma etches solved many of the problems of liquid etchants due to, for example, negation of surface tension issues. However, plasmas inherently contain ions, which are typically accelerated and implanted into the surface being etched. As device sizes continued to decrease to the nanoscale, ion implantation began to impair their functionality, resulting in residual stresses and impaired electrical operation.

To reduce or eliminate the problems of wet etches and plasma etches, dry chemical (i.e., non-plasma) etches increased in use during the formation of microelectronic devices. For example, xenon difluoride (XeF₂) has been employed as an isotropic silicon etchant (see, for example, H. F. Winters and J. W. Coburn, Applied Physics Letters 34(1), 70, 1979).

During an etch, the etch rate, etch depth, and etchant depletion are of particular interest so that the etch may be properly controlled. A method for real-time measurement of these and other parameters during an etch would be desirable.

### SUMMARY

The following presents a simplified summary in order to provide a basic understanding of some aspects of one or more embodiments of the present teachings. This summary is not an extensive overview, nor is it intended to identify key or critical elements of the present teachings, nor to delineate the scope of the disclosure. Rather, its primary purpose is merely to present one or more concepts in simplified form as a prelude to the detailed description presented later.

An embodiment of a method for determining etching parameters during an etch of a solid surface using an etching gas may include measuring a first pressure inside of an evacuated etching chamber containing a sample comprising the solid surface prior to initiation of the etch and initiating the etch and repeatedly exposing the solid surface to pulses of the etching gas. After initiating the etch, a second pressure inside of the etching chamber is measured, wherein the second pressure is different than the first pressure. At least one of a depletion of etchant, a depth of an etch within the solid surface, a volume of the solid surface that is etched by the etching gas, a volumetric etching rate of the solid surface by the etching gas, and a thickness etching rate of the solid surface by the etching gas are calculated, wherein the calculation comprises the use of the difference between the first pressure and the second pressure.

Another embodiment may include a method for determining etching parameters for pulsed xenon difluoride (XeF₂) etching of a solid silicon surface, the method including measuring a first pressure inside of an evacuated vacuum chamber containing a sample comprising the solid silicon surface prior to initializing an etch of the silicon surface, repeatedly exposing the silicon surface to pulses of XeF₂ vapor, and chemically reacting the silicon surface with the XeF₂ vapor to generate at least two different gaseous species of silicon fluoride. Subsequent to chemically reacting the silicon surface with the XeF₂ vapor, a second pressure inside of the vacuum chamber pressure is measured, wherein the second pressure is higher than the first pressure.

At least one of a depletion of the XeF₂, a depth of an etch within the silicon surface, a volume of the solid surface that is etched by the etching gas, a volumetric etching rate of the solid surface by the etching gas, and a thickness etching rate of the silicon surface by the etching gas is calculated, wherein the calculation comprises the use of the difference between the first pressure and the second pressure.

In another embodiment, a pulsed etching system for determining etching parameters for pulsed xenon difluoride (XeF₂) etching of a solid silicon surface may include a source chamber, an expansion chamber in fluid communication with the source chamber, a first valve configured to selectively separate the source chamber from the expansion chamber, an etch chamber in fluid communication with the source chamber, a second valve configured to selectively separate the etch chamber from the expansion chamber, and a pump in fluid communication with the source chamber, the expansion chamber, and the etch chamber, wherein the pump is configured to equalize pressure within source chamber, the expansion chamber, and the etch chamber.

### BRIEF DESCRIPTION OF THE DRAWINGS

The accompanying drawings, which are incorporated in and constitute a part of this specification, illustrate embodiments of the present teachings and together with the description, serve to explain the principles of the disclosure. In the figures:

FIG. 1 is a schematic depiction of an etching system in accordance with an embodiment of the present teachings;

FIG. 2 is a graph of pressure within a closed etch chamber during an etch according to an embodiment of the present teachings;

FIG. 3 is a graph of an etch rate and etch depth as a function of time for XeF₂ etching of silicon in a fixed volume chamber;

FIG. 4 is a graph of a second order analysis as described in equation 4 for the first 30 seconds of an etch of silicon using XeF₂;

FIG. 5 is a graph of percentage increase of chamber pressure as a function of time for etching silicon using XeF₂ in a fixed volume chamber;

FIG. 6 is a graph of etch depth and etch rate as a function of time for an etch of silicon using XeF₂ in a fixed volume chamber;

FIG. 7 is a graph of etched volume and volumetric etch rate as a function of time for an etch of silicon using XeF₂ in a fixed volume chamber;

FIG. 8 is a graph of linear etch rate as a function of time for an etch of silicon using XeF₂ in a fixed volume chamber;

FIG. 9 is a graph demonstrating a monotonic trend with increasing pressure that eventually saturates;

FIG. 10 is a scanning electron microscope (SEM) image of a device etched using an embodiment of the present teachings;

FIG. 11a is a schematic plan view, and FIG. 11b is a schematic cross section, of a device sample in an embodiment of the present teachings; and

FIGS. 12 and 13 are graphs showing an amount of polysilicon etched for each of four pulses for an etch of silicon using XeF₂ in an embodiment of the present teachings.

It should be noted that some details of the FIGS. have been simplified and are drawn to facilitate understanding of the present teachings rather than to maintain strict structural accuracy, detail, and scale.

### DETAILED DESCRIPTION

Reference will now be made in detail to exemplary embodiments of the present teachings, examples of which are illustrated in the accompanying drawings. Wherever possible, the same reference numbers will be used throughout the drawings to refer to the same or like parts.

Xenon difluoride (XeF₂) in its vapor phase spontaneously etches silicon (Si) at a rate as high as 10 μm/min, at room temperature, and sublimation of the solid phase XeF₂ occurs at 3.8 Torr (see, for example, K. R. Williams, Journal of Microelectromechanical Systems, 5, 1996 and Praxair Material Safety Data Sheet (2009), pp. 1-8). Thus, a vacuum system capable of achieving pressures only in the medium vacuum range is required for sublimation. The primary chemical reaction during an etch of Si (e.g., monocrystalline silicon or polycrystalline silicon) of XeF₂ with Si during an etch is given by Equation 1 (i.e., Eq. 1), shown below:

2XeF₂_{^{(g)}}+Si₍ₛ₎→SiF₄_{^{(g)}}+2Xe_{(g)}

XeF₂ may be employed as an etchant of Si in either a continuous etching system or a pulsed etching system. In a continuous etching system, an open-volume etching system (an open volume etch chamber) is utilized wherein a constant flow of XeF₂ is allowed to pass over the Si sample. This configuration has been found during early microelectronics fabrication when XeF₂ was initially used as an etchant. More recently, XeF₂ may be used in a pulsed etching configuration, where a pulse of XeF₂ is introduced into a closed-volume etching chamber (see, for example, P. B. Chu, J. T. Chen, R. Yeht, G. Lin, J. C. P. Huang, E. A. Warneket, and K. S. J. Pister, International Conference on Solid-State and Actuators (1997), pp. 665-668; I. W. T. Chan, K. B. Brown, R. P. W. Lawson, A. M. Robinson, Y. Ma, and D. Strembicke, in 1999 IEEE Canadian Conference on Electrical and Computer Engineering (IEEE, 1999), pp. 1637-1642; K. Sugano and O. Tabata, Int Symp. on Micromechatronics and Human Science 163, 1999). Closed-volume etching is commonly preferred because XeF₂ is typically used to remove sacrificial layers of Si where the etch rate need not be constant or controlled. Additionally, the requirements of the equipment for the closed-volume etching chamber are relaxed considerably compared to an open-volume etching chamber.

As may be determined in Eq. 1, the amount of stoichiometric gas (XeF_{2(g)}) prior to the etching reaction is equal to two moles (Si being a solid), while the amount of stoichiometric gas (SiF_{4(g)} and Xe_{2(g)}) after the etching reaction is three moles. If etching occurs in a fixed volume etching system, this increase in the number of moles of gas will result in an increase in pressure eventually. In this particular reaction, assuming that Eq. 1 is the only reaction, a pressure increase of 50% will occur in a closed system. Thus, in a pulsed etching system, correlations between the pressure and each of the depletion of the etchant, the etch depth, and the etch rate, and other factors tied to these values, may be made. Using the technique described herein, improved measurement and control may be attained.

While the embodiments of the present teachings are described herein with reference to etching Si with xenon difluoride, it is contemplated that this phenomenon may be exploited in any reaction occurring in a fixed volume where the number of moles either increases or decreases after undergoing a chemical reaction. In addition, this technique may be used for determining rate constants for chemical reactions as well.

In an embodiment, the depletion of etchant, the etched depth, and the etch rate of Si may be determined in a vapor phase etching system operating in a pulsed mode of operation. Real-time monitoring of the pressure results in real-time monitoring of the depletion of available etchant as the chemical reaction progresses. Etchant depletion may be determined by monitoring the pressure of the system. Once the pressure curve reaches its asymptotic value, it may be assumed that all available etchant has reacted. The etch depth (μm) and the etch rate (μm/min) may be determined from the same pressure data when the exposed (i.e., unmasked) area of the Si is known and is correlated to the number of Si atoms (monolayers) removed for a given pressure increase. Additionally, the rate constant for the reaction of XeF₂ with Si can be found using the same pressure data, and coupling it with knowledge of the chemical reactions involved.

Section II describes the experimental setup and methodology. Section III describes the results and method of analysis. Section IV explores the further utility of this method.

### Experimental Setup and Methodology

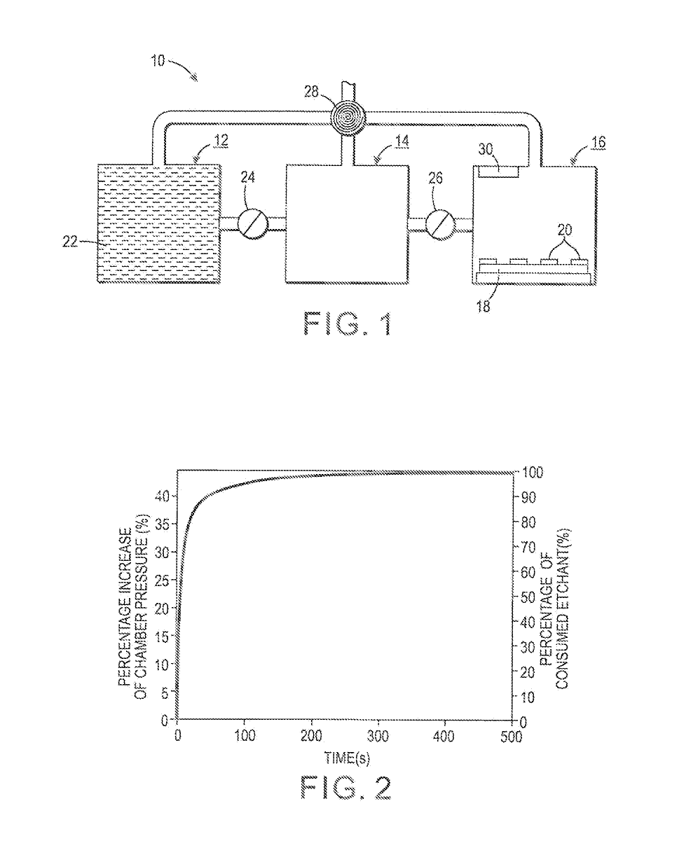

As depicted in FIG. 1, a custom-built pulsed etching system 10 was utilized in this work. The etching system included a source chamber 12, an expansion chamber 14 in fluid communication with the source chamber 12, and an etching chamber 16 in fluid communication with the expansion chamber 14. XeF₂ is moved through these chambers serially from the source chamber 12 to the etching chamber 16 through tubes or pipes to etch Si 18, for example a silicon wafer assembly including a silicon wafer 18 having an Si (100) crystal orientation. The wafer assembly may include an etch mask 20 having openings therein that expose a known surface area of the Si 18. It will be appreciated that the FIGS. are general depictions and that other structures may be added or existing structures may be removed or modified.

The following is a general overview of one possible embodiment of the present teachings utilized during an etching sequence. In an embodiment, the source chamber 12 is separated from the expansion chamber 14 by a first valve 24, and the expansion chamber 14 is separated from the etch chamber 16 by a second valve 26 which, at this point in the process, are both closed. Any air within the source chamber 12 is vented to the atmosphere, for example with a scroll pump 28, and replaced with XeF₂ 22. Pressure within each of the chambers 12, 14, 16 is equalized to a pressure of approximately 10 mTorr using, for example, the scroll pump 28, then the valves 24, 26 are placed in a closed position. Next, the source chamber 12 is pressurized with XeF₂ to a charge pressure of between about 2500 mTorr and about 5100 mTorr, for example about 3800 mTorr. The valve 24 between the source chamber 12 and the expansion chamber 14 is opened, thereby allowing the XeF₂ in the source chamber 12 to sublimate or expand into the expansion chamber 14. Once a desired pressure is equalized between the source chamber 12 and the expansion chamber 14, for example about 1 Torr for this study, the valve 24 is closed to isolate the expansion chamber 14 from the source chamber 12. Subsequently, XeF₂ within the expansion chamber 14 is released into the etch chamber 16 by opening valve 26, and the pressure within the expansion chamber 14 and the etch chamber 16 is allowed to equilibrate at, for example, between about 500 mTorr and about 630 mTorr of XeF₂, for example about 565 mTorr of XeF₂, at which time the etching chamber 16 is isolated from the expansion chamber 14 by closing valve 26. Pressure equilibration occurs in less than 300 milliseconds in the etching system 10. Prior to initiation of the etch, the pressure within the evacuated etching chamber is measured.

Initiation of etching of the exposed portions of the Si 18 by the XeF₂ within the etch chamber 16 then begins, and takes place over a period of time. The process described above is repeated or looped for a number of times sufficient to etch the Si to a desired depth. For these experiments, a pressure measurement was monitored at a rate of 1.0 Hz using a pressure sensor 30, for example a model PDR-C-2C available from MKS Instruments, Inc. of Andover, Mass., within the etch chamber 16. The pressure was monitored for a duration of 500 seconds to ensure that all available etchant within the etch chamber 16 was depleted.

In an embodiment, because the etching chamber is a closed volume and the number of gas moles within the etching chamber before the etching reaction and after the etching reaction are different (either higher or lower), the pressure within the etch chamber 16 may for real-time monitoring to extrapolate various etch properties. These properties include the time at which complete depletion of the etchant occurs, the depth of the etch, the etch rate, and the rate constant for XeF₂ etching of Si. Thus if a reaction between the etchant and target material either increases or decreases the number of moles present in the gaseous phase, this will be reflected as a change in the pressure of the system. Note that etching chambers of plasma etching systems are typically an open volume in which gases flow continuously and a constant pressure is attained by adjustment of flow rates and valves, in contrast to a closed etch chamber of the present teachings.

Determination of the etch rate, etch depth and complete depletion of the etchant may be performed with two data sets, including the pressure within the etching chamber and the area of exposed Si for the sample being etched (e.g., the area exposed by any etch mask).

For the present teachings, a leak check of the etching chamber was performed and the leak rate was determined to be 6 mTorr/min. Thus over the period of etching, the pressure increase is approximately 50 mTorr which is less than 8% of the initial pressure of the etchant in the etching chamber. Reported data corrects for error due to leaks and residual gas. The area of exposed Si may be obtained through optical measurement or from a calculation of the area of the etch sample exposed by the mask. After etching, verification of etched depths was found by using a profilometer. A comparison of the etch depth extrapolated from the measured pressure data with the etch depth measured with a profilometer differed by no more than 3%.

The method discussed herein allows real-time data analysis during the etch by monitoring or sampling etch chamber pressure, with all other parameters being known a priori. In an embodiment, an automated software program receives continuous or sampled etch chamber pressure data and may output data relative to the current percent of etchant depletion for the measured pressure up to complete depletion of the etchant, the current etch depth, the etch rate. The constant for XeF₂ etching of Si (or for another etchant used to etch a different material) can be specified before etching begins. In an embodiment, pressure data may be collected continuously or sampled periodically, for example at 1 Hz, to provide real-time display of the extrapolated etching parameters. More frequent or continuous pressure data measurements provide better granularity in the etching parameters but may not be necessary depending on the etch rate and etch duration.

Samples for this work included a Si (100) etch target patterned with a mask of silicon dioxide (SiO₂). With XeF₂ as an etchant, a Si:SiO₂ etch selectivity of more than 1000:1 may be attained (see, for example, D. E. Ibbotson, J. A. Mucha, and D. L. Flamm, J. Appl. Phys. 56 (10), (1984); D. E. Ibbotson, D. L. Flamm, J. A. Mucha, and V. M. Donnelly, Appl. Phys. Lett., 44(12), (1984); D. L. Flamm, V. M. Donnelly, and J. A. Mucha, Journal of Applied Physics, 52(5), (1981); and M. Kojima, H. Kato, M. Gatto, S. Morinaga, and N. Ito, J. Appl. Phys. 3, 1991). Any native oxide or other etch inhibitors may be removed prior to the etch For example, a native oxide layer may be removed from a silicon etch target using a 10:1 hydrofluoric acid for 10 seconds, followed by a subsequent dehydration bake in an inert atmosphere for approximately 5 minutes. Removal of the native oxide or other etch inhibitor allows for etching to begin immediately due to the low etch rate of, for example, SiO_{z}in XeF₂ (nearly 0 nm/min). A dehydration bake may be performed to remove any adsorbed water, which can react with XeF₂ to form HF in the etching chamber. The XeF₂ used in this work was of 99.99% purity, available from SynQuest Lab. Inc. of Alachua, Fla.

### Experimental Results

Referring to the reaction in Eq. 1, for every 2 moles of gaseous XeF₂ reactant, 3 moles of gaseous product will be created (1 mole SiF₄ and 2 moles Xe). From the ideal gas law shown as Equation 2 (i.e., Eq. 2) below:

PV=nRT

where P is pressure, V is the volume, n is the number of moles, R is the gas constant, and T is the temperature, Eq. 2 shows that increasing the number of moles proportionally increases the pressure in the closed etch chamber. For XeF₂, an increase of 50% in pressure is predicted by Eq. 1.

FIG. 2 shows the percentage increase of chamber pressure as a function of time for etching of Si with XeF₂ in a fixed volume. Data indicates the pressure monotonically increases with time. A saturation pressure is eventually reached at about 144.6% of the initial pressure indicating that the reactant has been depleted. The final pressure is an indication that there has been a 44.6% increase in the number of moles of gas in the system. Again, the initial pressure of the etching chamber is 565 mTorr. In this experiment, Si is present in an amount greater than can be consumed by the XeF₂ released into the chamber, which is verified by the presence of Si after all etchant has been reacted. An etch duration of 500 seconds was selected to ensure complete depletion of the reactant etchant, leaving only byproducts in the system. Clearly, the pressure in FIG. 2 is approaching an asymptotic value. It was found that the final measured pressure increase within the etch chamber after all etchant was reacted was consistently less than the predicted 50% by approximately 4.7%. By averaging the results of 10 experiments, a value of 45.3% was found, with a standard deviation of 0.96%. The literature indicates that reactions of XeF₂ with Si can take chemical reaction pathways other than Eq. 1 (see, for example, M. J. Mitchell, M. Suto, and L. C. Lee, Journal of Vacuum Science & Technology B 5 (5), 1987). While the primary reaction is described by Eq. 1, a secondary reaction occurs as well as described in Equation 3 (i.e., Eq. 3) shown below:

3XeF₂(g)+Si(s)→Si₂F₆(g)+3Xe(g)

For this reaction, 3 moles of the reactant gas creates 4 moles of gaseous product, resulting in a 33% increase in the pressure, in contrast to the 50% increase of Eq. 1. To determine the contributions of each of the reactions in Eq. 1 and Eq. 3, an analysis was performed to determine the stoichiometry of each of the gasses throughout the experiment.

Using the assumption that both reactions occur at a constant rate throughout the etch and that all the XeF₂ is consumed, it was found that the fraction of XeF₂ that reacts due to Eq. 1 is 0.6761 and due to Eq. 3 is 0.3239. Reactions occurring in these fractions result in an overall etch chamber pressure increase of 44.6% upon complete consumption of the reactant gas. This pressure increase falls within the experimental error recorded, cf. 45.3% t 0.96%. Thus a 144.6% increase in pressure theoretically indicates that all reactions are complete and the etchant is depleted.

By comparing the current pressure to the theoretically predicted final pressure, one can determine the percentage of etchant consumed at any given time using the measured etch chamber pressure data. Using this method, the right-hand y-axis of FIG. 2 was determined.

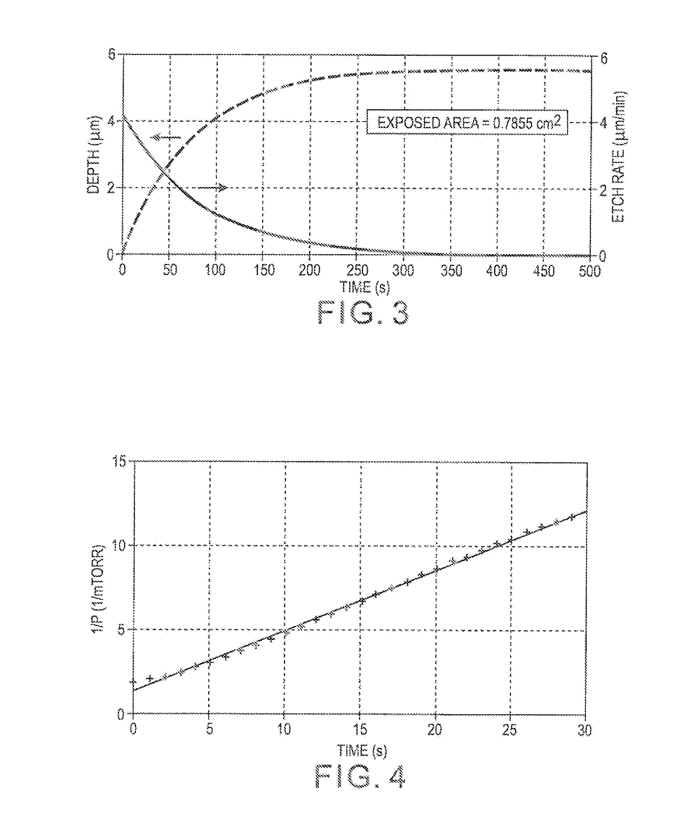

From the pressure data in FIG. 2, the etch rate and etch depth may also be calculated. The etch depth may be found by correlating the planar density of Si, 6.78(10)¹⁴ atoms/cm², with the increase in pressure. More specifically, the planar density multiplied by the exposed area of Si results in the number of atoms present at the surface that are available for etching. In this approximation, it is assumed that Si is removed one monolayer at a time. Next, it is also assumed that each mole of Si atoms on the surface that is etched will lead to an increase in the number of moles in the gas phase of 1.446 times, via equations 1 and 3 as previously discussed. With this information, the depth of Si etched may be plotted as shown in FIG. 3. By taking the numerical derivative of the etch depth with respect to time (finite difference approximation), the etch rate can be determined, as shown in FIG. 3.

FIG. 3 plots the etched depth and etch rate as a function of time for XeF₂ during etching of Si in a fixed volume. Etch depth is determined using the pressure data from FIG. 2 and information about the chemical reaction and material properties of Si. The etch rate is determined by taking the numerical derivative of the etched depth with respect to time using the finite difference approximation. It will be appreciated that FIG. 3 reveals other insight into the etching of Si with XeF₂ First, the depth as a function of time is considered. A monotonic (not linear) increase in depth with time is seen to track the pressure increase. This is expected due to its derivation from the pressure data and chemical reaction. Using this piece of information allows for control of the etched depth of a sample. The etch rate for the sample is monotonically (i.e., not linearly) decreasing. Previous reports on the etch rate of Si using XeF₂ report only a single number, which appears to be an average etch rate determined by dividing by etched depth by the duration of the etch. Interpretation of the etch rate in this manner is misleading, as the etch rate is the result of complex set of surface reactions between the XeF₂ and Si, and is not constant or linearly varying with time. Using the method disclosed herein demonstrates that the etch rate varies from over 4.2 μm/min to nearly 0 μm/min in a nonlinear manner.

From a technological standpoint, the etch rate data are useful as well as they may be used to determine when to stop an etch in order to optimize the speed of a process. For example, to minimize the total etch time, an etch might be run for a shorter duration with multiple pulses versus a longer duration of time with fewer pulses. Alternatively, the etchant use may be maximized while minimizing the etch duration, for example, by stopping the etch when the etch rate is found to be approximately zero. This is the equivalent to monitoring for when a pressure increase within the etch chamber becomes equal to zero (or, more exactly, when the pressure increase is equivalent to the leak rate of the etch chamber).

The same pressure data also allows for determination of a rate constant for the reaction of XeF₂ with Si. Previously it was shown that the reaction pathways given by Eq. 1 and Eq. 3 describe the manner with which XeF₂ reacts with Si. These reactions occur on the solid, exposed surface of the silicon and, as such, the rate constant found in this work is an ‘apparent’ or ‘effective’ rate constant due to it being a set of complex surface reactions and not purely reactions of the gas phase. FIG. 4 is a plot of the 2^{nd} order analysis plot as described in Eq. 4 below for the first 30 seconds. Equation 4 describes the stoichiometry of XeF₂ undergoing both reaction described in Eqs. 1 and 3. The slope is the apparent reaction rate constant (k) and has a value of 0.308 mTorr⁻¹ sec⁻¹. FIG. 4 shows that the inverse of the partial pressure of XeF₂ increases linearly with time for the first 30 seconds of the reaction. This type of dependence is typical for a second-order reaction rate (see, for example, H. S. Fogler, Elements of Chemical Reaction Engineering, 4th ed., Prentice Hall International Series, 2006) shown below as Equation 4 (i.e., Eq. 4):

$$- \frac{d {P}_{{XeF}_{2}}}{d t} = {kP}_{{XeF}_{2}}^{2}$$

where P_{XeF2} is the pressure of the XeF₂ in the system as determined by the stoichiometry analysis of the gasses as previously described, and k is the apparent rate constant for the reactions occurring between XeF₂ and Si. The slope of the line in FIG. 4 corresponds to k, and has a value of 0.308 mTorr⁻¹ sec⁻¹.

Additional Validation of Method: Effect of Varying Surface Area of Exposed Silicon

Additional studies were performed in which the surface area of the exposed Si was increased to further validate the previous results. Increasing the area of exposed Si increases the rate at which the reactant gas (e.g. XeF₂) is used and thus increases the rate of pressure increase.

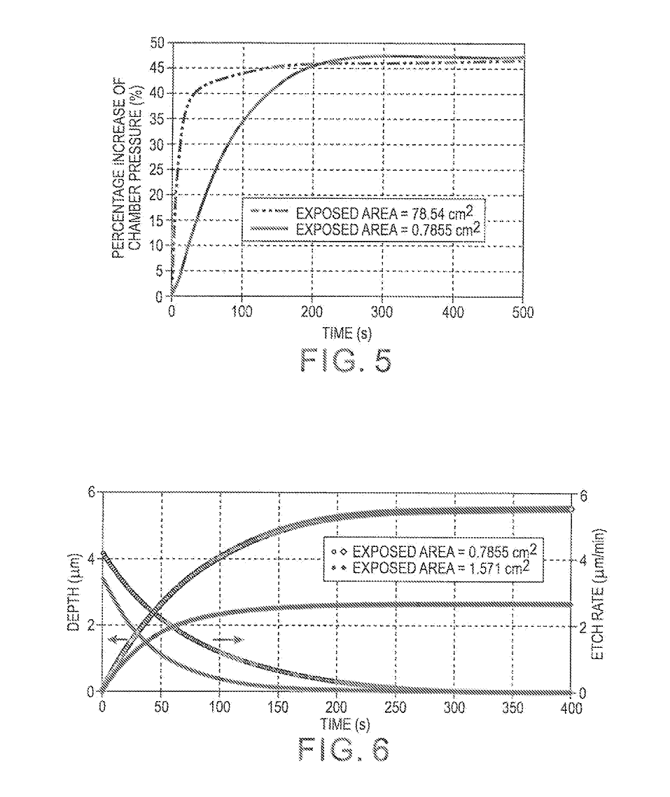

FIG. 5 plots the percentage increase of chamber pressure as a function of time for etching of Si with XeF₂ in a fixed volume. Data is presented for two different exposed surface areas of Si. The curve with the higher initial rate is for a larger surface area (78.54 cm²) and the curve with lower initial rate is for a smaller surface area (0.7855 cm²). In both cases, the data indicates a monotonically increasing value of pressure that saturates with time. The saturation pressures are 144.6% of the initial pressure indicating that the reactant has been depleted and that there has been a 44.6% increase in the number of moles of gas in the system. FIG. 5 demonstrates how the pressure change in the chamber is affected by the amount of Si exposed directly. The leftmost curve is for an area of exposed Si equivalent to 78.54 cm². The rightmost curve is for an exposed area of 0.7855 cm². Note that the rate of pressure increase for the sample with a larger exposed area of Si is significantly faster than that of the smaller exposed area. Larger exposed surface areas allow for an increased number of surface reactions. Furthermore, note that both curves asymptotically tend toward 45.3%, as did the data presented earlier in FIG. 2.

FIG. 6 plots the etched depth and etch rate as a function of time for XeF₂ etching of Si in a fixed-volume chamber. Data is presented for two samples each with a different exposed surface area of Si. The larger the value of exposed Si surface area the lower the etched depth and the lower the etch rate. Etch depth is determined using the pressure data from during etching and information about the chemical reaction and material properties of Si. The etch rate is determined by taking the numerical derivative of the etched depth with respect to time using the finite difference approximation. Again, using the exposed surface area allows for determination of the etch depth and etch rate. The two sets of curves correspond to exposed surface areas of 1.571 cm² and 0.7855 cm² respectively. Increasing the amount of exposed surface area causes the etched depth to reach its maximum values within a shorter period of time, with a decreased final etch depth. In other words, the maximum value of etched depth attained decreases for an increase in exposed surface area, but maintains a constant ratio between the exposed area and etched depth. Etch rate curves shift to lower values for larger values of exposed areas of Si. This indicates that the establishment and completion of etching from depletion of the XeF₂ etchant has occurred over a shorter period of time.

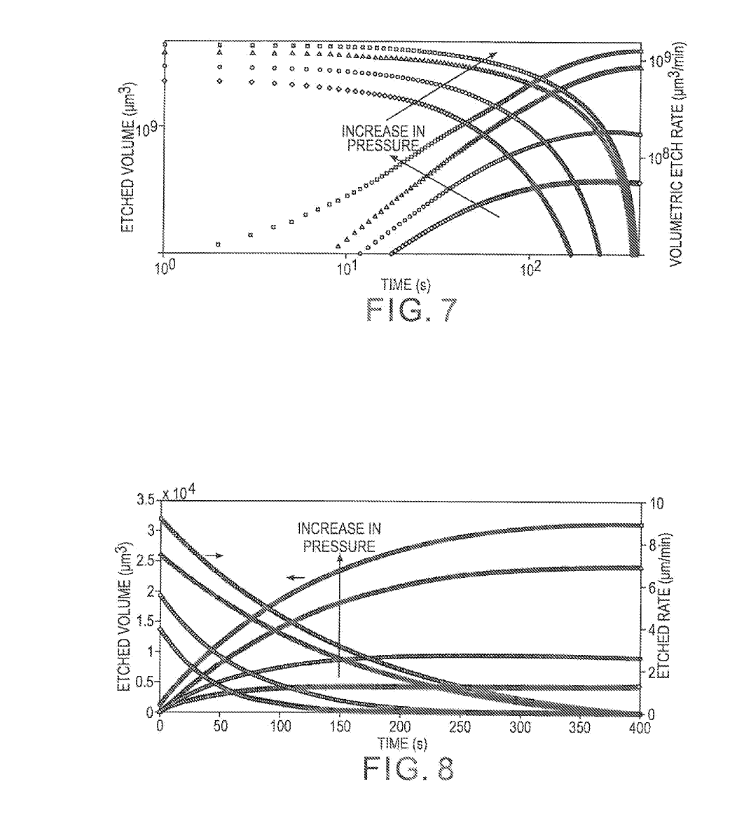

In a second study, an area of exposed Si (1.57 cm²) was etched using differing pressures of XeF₂. Due to the varying initial pressure, different volumes of Si were removed at different rates as depicted in FIGS. 7 and 8, which depict etch rates for initial expansion chamber pressures of 1, 2, 3, and 3.8 Torr, which correspond to initial etching chamber pressures of 0.63, 1.2, 1.72, and 2.23 Torr respectively. The arrows indicate the direction of increasing pressure. FIG. 7 is a graph of the etched volume and volumetric etch rate as a function of time, and FIG. 8 is the linear etch rate as a function of time. Sets of curves such as those in FIG. 7 identify the time at which devices sitting on sacrificial layers of Si are released. It is often desirable to remove varying volumes of sacrificial Si in order to release freestanding micro or nanostructures. Determining the volume of Si removed in these cases is usually not as easy as observing that a depth of Si has been removed from around the device and multiplying by the surface area of the exposed silicon. Most micro/nanostructures have complex features and release holes under and around each of which a varying amount of Si is removed due to trenching and loading effects (see, for example, B. Bahreyni and C. Shafai, J. Vac. Sci. Technol. A Vacuum, Surfaces, Film. 20, 1850 (2002). Though the graphed data is for a large area of exposed Si that does not have trenching or loading effects, it is useful for gauging the maximum volumetric etch rate attainable.

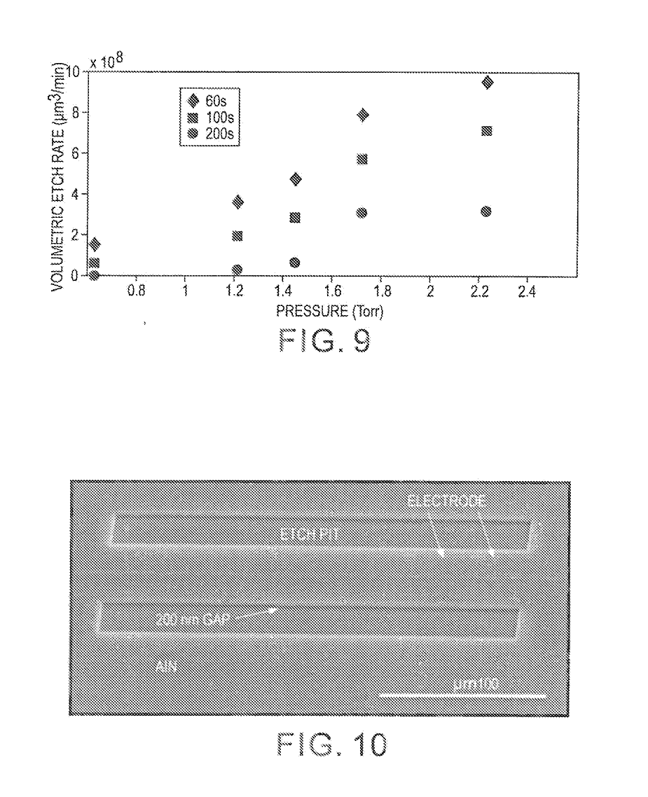

FIGS. 7 and 8 also supply information about the etch rate as a function of pressure. Increasing the pressure in the etching system will typically lead to higher etch rates, which is typically desirable in many applications. For example increasing pressure from 630 mTorr to 2.23 Torr increases the initial etch rate from 3.92 μm/min to 9.18 μm/min (FIG. 8). However, an excessively high etch rate may result in inadvertent and detrimental heating of the micro/nanostructures because XeF₂ etching of Si is an exothermic reaction (see, for example, F. a. Houle, J. Chem. Phys. 87, 1866 (1987); R. C. Hefty, J. R. Holt, M. R. Tate, and S. T. Ceyer, J. Chem. Phys. 130, 164714 (2009)). The data in FIG. 9 demonstrates a monotonic trend with increasing pressure that eventually saturates. Some observers (for example, K. Sugano and O. Tabata, J. Micromech. Microeng. 12, 911 (2002)) have shown a linear trend with increased charge (i.e., expansion chamber) pressure. However, this data only reached an etching chamber pressure of 233 mTorr. Data in FIG. 9 further demonstrates a linear trend for this pressure range, and also reaches much higher pressures which further demonstrates that etching at elevated pressures above approximately 2 Torr does not dramatically increase the etch rate. Saturation of the etch rate with increasing pressure suggests again that reactions may be transport limited, i.e. the flux of reactants into and products from etched surfaces are competing with one another. For identical samples this trend should hold regardless of the layout of the exposed Si until the point where feature sizes are on the order of the mean free path of the gas particles. Around this dimension transport in and out of the etch zone will be impeded and etching will considerably slower. FIG. 9 shows the volumetric etch rate as a function of etching chamber pressure at different time of etch period (60 s, 100 s, 200 s) for XeF₂ etching of Si. Data is presented for an exposed area of 1.57 cm², and demonstrates a repeatable trend of volumetric etch rate of Si with XeF₂ with respect to the initial pressure of the etching chamber for every particular etch period.

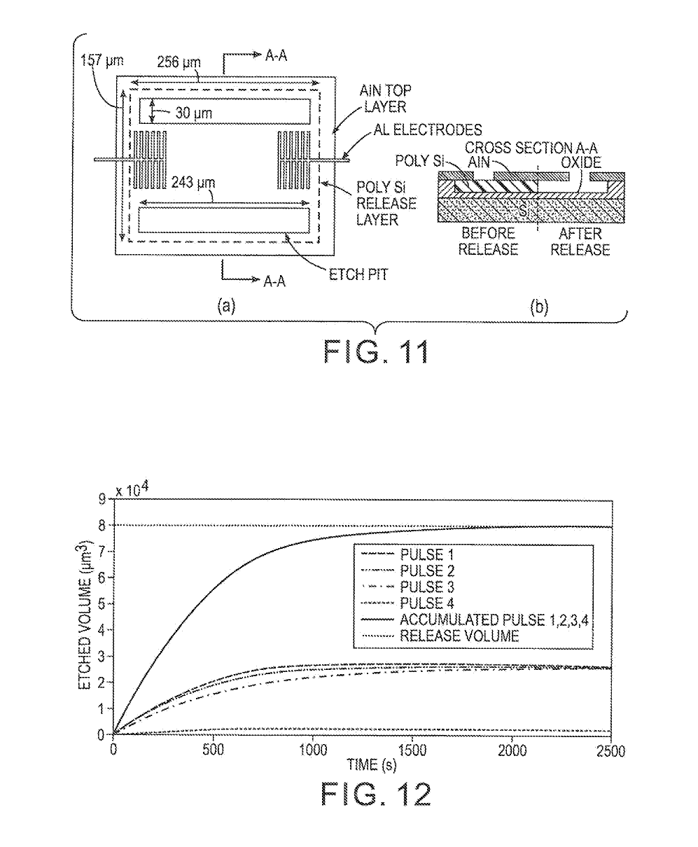

In the final study an AlN resonator is released using pulses of XeF₂ to remove a sacrificial polysilicon layer. FIG. 10 is a SEM image of a released device, including an active piezoelectric material layer of aluminum nitride (AlN) with patterned aluminum (Al) electrodes. On either side of the electrodes are two rectangular etch pits. These pits gave access to a polysilicon release layer as depicted in the schematic depiction of FIG. 11a (plan view) and FIG. 11b (cross section along A-A of FIG. 11a) that had previously resided beneath the resonator.

The polysilicon release layer of FIG. 11 has a well-defined volume. A total volume of 8.03×10⁴ μm³ of polysilicon was used per AlN resonator for the sacrificial layer. The etch pit openings are 243 μm×30 μm, and 2.92×10⁴ μm³ of polysilicon is immediately available for vertical etching in the opening of the pit However, an additional 5.11×10⁴ of polysilicon is recessed under the AlN active layer, which is laterally etched and, as such, etches at a lower rate than does the polysilicon that is exposed immediately under the etch pit.

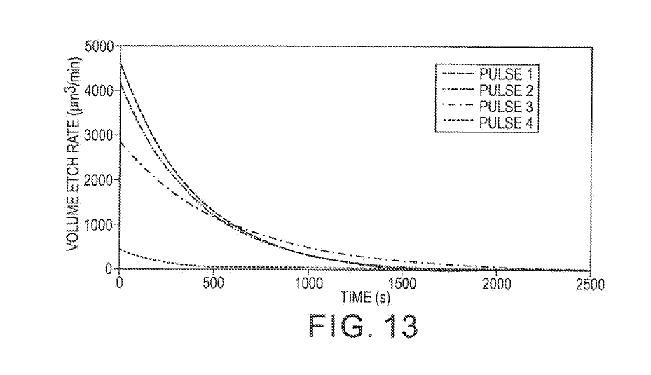

FIGS. 12 and 13 are graphs showing the amount of polysilicon etched for each of four pulses that simultaneously released 16 AlN resonators formed on the same die as well as the etch rates for each pulse. FIG. 12 shows the volume etched for each pulse, while FIG. 13 shows the volumetric etch rate, using XeF₂ to etch polysilicon in a fixed volume chamber. Etched volume was determined using the pressure data from during etching and stoichiometric information relative to the chemical reaction as well as material properties of silicon. The volumetric etch rate was determined by taking the numerical derivative of the volumetric etched depth with respect to time using the finite difference approximation. The first three pulses etch the same volume of Si due to the availability of polysilicon to be etched. A final fourth pulse is necessary to fully release the device, but the etched volume for the fourth pulse is less than the previous three pulses, because at a certain point there is no remaining polysilicon to be etched. In FIG. 12, the solid horizontal line demarcates the volume of polysilicon under all 16 resonators. A summation of the removed volumes (accumulated pulse) from all four pulses demonstrates that all polysilicon was removed. As verification that all polysilicon is removed, a fifth pulse was attempted, and the outcome demonstrated that there was no increase in pressure whatsoever, thereby indicating that all polysilicon was etched.

FIG. 13 shows the rate at which the polysilicon was etched for each pulse. Initial etch rates decrease with increasing pulse number. This is due to the accessibility of the etchant to the polysilicon to be etched. Initially, the polysilicon in the etch pit opening is available to the etchant via a line-of-sight. After the first pulse this volume of polysilicon has been nearly all removed and the second pulse must then begin to laterally etch the polysilicon under the AlN active layer. The third pulse is only laterally etching the polysilicon from under the AlN. Finally, the fourth pulse is presumably removing the polysilicon in the furthest corners of the polysilicon release layers, which contains very little polysilicon and thus the etch stops without depleting all the etchant. In FIG. 13, the initial rates continually decrease for each pulse. At approximately 500 seconds, the etch rates flip and the fastest etch rate is for pulse 3 and the slowest etch rate is for pulse. At this time, almost all the etchant has been depleted during pulse 1 while, for pulse 3, a relatively large amount remains and thus can sustain a larger etch rate.

### CONCLUSION

Thus an embodiment of the present teachings provide a tool for directly measuring and/or calculating various etch-related parameters, such as the depletion of etchant, the depth of an etch within a solid surface, a volume of a solid surface that is etched by an etching gas, a volumetric etching rate of a solid surface by the etching gas, an etching rate of a solid surface by an etch gas, or any other parameter derived from observation of the difference between a first pressure measured before initiating an etch and a second pressure measured after initiating an etch. In an embodiment, the etch gas may be an XeF₂ vapor and the etch may be performed using a pulsed etching system. This technique may rely on a single measurement during the etch process, specifically the pressure change over time within in a dosed etching system, combined with prior knowledge of the chemical reactions involved. It was shown that the pressure increased to 145.3%±0.96% of its initial value, which was predicted by using the two most favorable reaction pathways for XeF₂ etching of Si described in equations 1 and 3 above. Using the pressure data, the exposed surface area, and planar density of Si atoms on the surface of the Si, the etched depth was determined. Taking the time derivative of the depth data yielded the etch rate. A monotonic increase in the pressure corresponded to a monotonically decreasing etch rate.

Using an initial pressure of 565 mTorr, etch rates higher than 4.1 μm/min were recorded. From the stoichiometry of the gas, an apparent rate constant for the reaction of XeF₂ with Si was found. This reaction was determined to be a second-order reaction because the inverse of the partial pressure of XeF₂ varied linearly with time. The measured rate constant was found to be 0.308 mTorr⁻¹ sec⁻¹. Additional studies were conducted that showed the direct correlation between exposed surface area of Si and the depth etched and etch rate. In particular, it was found that larger values of exposed Si surface area lead to lower depths etched and lower etch rates for a constant initial pressure (and constant volume) of XeF₂.

Notwithstanding that the numerical ranges and parameters setting forth the broad scope of the present teachings are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less than 10” can assume negative values, e.g. −1, −2, −3, −10, −20, −30, etc.

While the present teachings have been illustrated with respect to one or more implementations, alterations and/or modifications can be made to the illustrated examples without departing from the spirit and scope of the appended claims. For example, it will be appreciated that while the process is described as a series of acts or events, the present teachings are not limited by the ordering of such acts or events. Some acts may occur in different orders and/or concurrently with other acts or events apart from those described herein. Also, not all process stages may be required to implement a methodology in accordance with one or more aspects or embodiments of the present teachings. It will be appreciated that structural components and/or processing stages can be added or existing structural components and/or processing stages can be removed or modified. Further, one or more of the acts depicted herein may be carried out in one or more separate acts and/or phases. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items can be selected. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated embodiment Finally, “exemplary” indicates the description is used as an example, rather than implying that it is an ideal. Other embodiments of the present teachings will be apparent to those skilled in the art from consideration of the specification and practice of the disclosure herein. It is intended that the specification and examples be considered as exemplary only, with a true scope and spirit of the present teachings being indicated by the following claims.

Terms of relative position as used in this application are defined based on a plane parallel to the conventional plane or working surface of a workpiece, regardless of the orientation of the workpiece. The term “horizontal” or “lateral” as used in this application is defined as a plane parallel to the conventional plane or working surface of a workpiece, regardless of the orientation of the workpiece. The term “vertical” refers to a direction perpendicular to the horizontal. Terms such as “on,” “side” (as in “sidewall”), “higher,” “lower,” “over,” “top,” and “under” are defined with respect to the conventional plane or working surface being on the top surface of the workpiece, regardless of the orientation of the workpiece.

1. A method for determining etching parameters during an etch of a solid surface using an etching gas, the method comprising:
measuring a first pressure inside of an evacuated etching chamber containing a sample comprising the solid surface prior to initiation of the etch;
initiating the etch and repeatedly exposing the solid surface to pulses of the etching gas;
after initiating the etch, measuring a second pressure inside of the etching chamber, wherein the second pressure is different than the first pressure; and
calculating at least one of a depletion of etchant, a depth of an etch within the solid surface, a volume of the solid surface that is etched by the etching gas, a volumetric etching rate of the solid surface by the etching gas, and a thickness etching rate of the solid surface by the etching gas, wherein the calculation comprises the use of the difference between the first pressure and the second pressure.

2. The method of claim 1, further comprising repeatedly exposing the solid surface to xenon difluoride (XeF₂) during the repeated exposure of the solid surface to the pulses of the etching gas.

3. The method of claim 2, further comprising repeatedly exposing a silicon solid surface to the XeF₂ during the repeated exposure of the solid surface to the pulses of the etching gas.

4. The method of claim 1, further comprising:
introducing the etching gas into a source chamber prior to introducing the etching gas into the etching chamber;
increasing a pressure within the source chamber;
opening a first valve to release the etching gas from the source chamber into an expansion chamber; and
opening a second valve to release the etching gas from the expansion chamber into the etching chamber.

5. The method of claim 4, further comprising equalizing pressures within the source chamber, the expansion chamber, and the etching chamber prior to introducing the etching gas into the source chamber.

6. The method of claim 1, further comprising exposing the solid surface to at least one additional pulse of the etching gas subsequent to measuring the second pressure inside of the etching chamber.

7. A method for determining etching parameters for pulsed xenon difluoride (XeF₂) etching of a solid silicon surface, the method comprising:
measuring a first pressure inside of an evacuated vacuum chamber containing a sample comprising the solid silicon surface prior to initializing an etch of the silicon surface;
repeatedly exposing the silicon surface to pulses of XeF₂ vapor;
chemically reacting the silicon surface with the XeF₂ vapor to generate at least two different gaseous species of silicon fluoride;
subsequent to chemically reacting the silicon surface with the XeF₂ vapor, measuring a second pressure inside of the vacuum chamber pressure, wherein the second pressure is higher than the first pressure;
calculating at least one of a depletion of the XeF₂, a depth of an etch within the silicon surface, a volume of the solid surface that is etched by the etching gas, a volumetric etching rate of the solid surface by the etching gas, and a thickness etching rate of the silicon surface by the etching gas, wherein the calculation comprises the use of the difference between the first pressure and the second pressure.

8. The method of claim 7, wherein the chemical reaction of the silicon surface with the XeF₂ vapor comprises the following two chemical reactions:
2XeF₂_{^{(g)}}+Si₍ₛ₎→SiF₄_{^{(g)}}+2Xe_{(g)}.
and
3XeF₂(g)+Si(s)→Si₂F₆(g)+3Xe(g).

9. The method of claim 7, further comprising:
introducing the XeF₂ vapor into a source chamber prior to introducing the XeF₂ into the etching chamber;
increasing a pressure within the source chamber;
opening a first valve to release the XeF₂ vapor from the source chamber into an expansion chamber; and
opening a second valve to release the XeF₂ vapor from the expansion chamber into the etching chamber.

10. The method of claim 9, further comprising equalizing pressures within the source chamber, the expansion chamber, and the etching chamber prior to introducing the XeF₂ into the source chamber.

11. A pulsed etching system for determining etching parameters for pulsed xenon difluoride (XeF₂) etching of a solid silicon surface, comprising:
a source chamber;
an expansion chamber in fluid communication with the source chamber;
a first valve configured to selectively separate the source chamber from the expansion chamber;
an etch chamber in fluid communication with the source chamber;
a second valve configured to selectively separate the etch chamber from the expansion chamber; and
a pump in fluid communication with the source chamber, the expansion chamber, and the etch chamber, wherein the pump is configured to equalize pressure within source chamber, the expansion chamber, and the etch chamber.

12. The pulsed etching system of claim 11, wherein the pump is further configured to pressurize the source chamber with xenon difluoride (XeF₂) to a charge pressure of about 3800 mTorr with the first valve in a closed position.

13. The pulsed etching system of claim 12 wherein, subsequent to the pressurizing of the source chamber, the first valve is configured to open to allow the XeF₂ within the source chamber to expand into the expansion chamber.

14. The pulsed etching system of claim 13 wherein:
the source chamber and the expansion chamber are configured to pressure equalize after opening the first valve; and
the second valve is configured to open after the source chamber and the expansion chamber are pressure equalized to release XeF₂ from the expansion chamber into the etch chamber.

15. The pulsed etching system of claim 14, wherein the source chamber and the expansion chamber are configured to pressure equalize at a pressure of about 1 Torr.

16. The pulsed etching system of claim 14, wherein the first valve is configured to close and the second valve is configured to open after equalizing pressure between the source chamber and the expansion chamber to equalize pressure between the expansion chamber and the etch chamber.

17. The pulsed etching system of claim 16, wherein the expansion chamber and the etch chamber are configured to equalize at a pressure of about 565 mTorr.

18. The pulsed etching system of claim 16, further comprising a pressure sensor within the etching chamber, wherein the pressure sensor is configured to measure a first pressure within the etching chamber prior to initiating an etch and to measure a second pressure within the etching chamber after initiating an etch.
